(19) United States
(12) Patent Application Publication
(10) Pub. No.: US 2026/0255770 A1
(43) Pub. Date: Aug. 27, 2026

(54) LIGHT EMITTING APPARATUS, PROJECTOR, AND ELECTRONIC INSTRUMENT

(71) Applicant: SEIKO EPSON CORPORATION, Tokyo (JP)

(72) Inventors: Yasuto AKATSUKA, CHINO-SHI (JP); Kentaro TAKAYANAGI, CHINO-SHI (JP)

(73) Assignee: SEIKO EPSON CORPORATION, Tokyo (JP)

(21) Appl. No.: 19/433,024

(22) Filed: Dec. 25, 2025

(30) Foreign Application Priority Data
Dec. 27, 2024 (JP) 2024-231638

(51) Int. Cl. H10H 29/856; H10H 20/819

(52) U.S. Cl. CPC H10H 29/856; H10H 20/819

(57) ABSTRACT

A light emitting apparatus including: a first stack including a first semiconductor layer, a second semiconductor layer and a first light emitting layer; a second stack including a third semiconductor layer, a fourth semiconductor layer and a second light emitting layer; a fifth semiconductor layer between the second and fourth semiconductor layers, being in contact with the second and fourth semiconductor layers; a reflector between the first and second light emitting layers; a first electrode on a side opposite the first light emitting layer with the first semiconductor layer interposed therebetween; a second electrode on a side opposite the second light emitting layer with the third semiconductor layer interposed therebetween; and a common electrode on a side of the second, fourth and fifth semiconductor layers, and configured to transmit light generated in the first light emitting layer and the second light emitting layer.

The present application is based on, and claims priority from JP Application Serial Number 2024-231638, filed Dec. 27, 2024, the disclosure of which is hereby incorporated by reference herein in its entirety.

### BACKGROUND

### 1. Technical Field

The present disclosure relates to a light emitting apparatus, a projector, and an electronic instrument.

### 2. Related Art

Light emitting elements such as light emitting diodes (LEDs) are used in electronic instruments such as displays.

WO 2019/038961, for example, describes a micro-LED element including a nitride semiconductor layer configured with an N-type layer, a light emitting layer, and a P-type layer, a buried layer, a P-side electrode layer, and a common N-side electrode layer. The common N-side electrode layer is a transparent conductive film made, for example, of ITO.

WO 2019/038961 is an example of the related art.

ITO (indium tin oxide) has resistivity greater than those of metals used as the material of typical wiring. The current injected into the light emitting layer therefore decreases, so that the luminance of the light from the light emitting layer decreases in some cases.

### SUMMARY

An aspect of a light emitting apparatus according to the present disclosure includes:
a first stack including a first semiconductor layer having a first conductivity type, a second semiconductor layer having a second conductivity type different from the first conductivity type, and a first light emitting layer provided between the first semiconductor layer and the second semiconductor layer;
a second stack including a third semiconductor layer having the first conductivity type, a fourth semiconductor layer having the second conductivity type, and a second light emitting layer provided between the third semiconductor layer and the fourth semiconductor layer;
a fifth semiconductor layer provided between the second semiconductor layer and the fourth semiconductor layer, being in contact with the second semiconductor layer and the fourth semiconductor layer, and having the second conductivity type;
a reflector provided between the first light emitting layer and the second light emitting layer;
a first electrode provided on a side opposite the first light emitting layer with the first semiconductor layer interposed therebetween;
a second electrode provided on a side opposite the second light emitting layer with the third semiconductor layer interposed therebetween; and
a common electrode provided on a side opposite the first light emitting layer with the second semiconductor layer interposed therebetween, on a side opposite the second light emitting layer with the fourth semiconductor layer interposed therebetween, and on a side opposite the reflector with the fifth semiconductor layer interposed therebetween, and configured to transmit light generated in the first light emitting layer and light generated in the second light emitting layer.

An aspect of a projector according to the present disclosure includes
the light emitting apparatus described above.

An aspect of an electronic instrument according to the present disclosure includes
the light emitting apparatus described above.

### BRIEF DESCRIPTION OF THE DRAWINGS

FIG. 1 is a cross-sectional view diagrammatically showing a light emitting apparatus according to an embodiment of the present disclosure.

FIG. 2 is a cross-sectional view diagrammatically showing a step of producing the light emitting apparatus according to the present embodiment.

FIG. 3 is a cross-sectional view diagrammatically showing another step of producing the light emitting apparatus according to the present embodiment.

FIG. 4 is a cross-sectional view diagrammatically showing another step of producing the light emitting apparatus according to the present embodiment.

FIG. 5 is a cross-sectional view diagrammatically showing a light emitting apparatus according to a first variation of the present embodiment.

FIG. 6 is a cross-sectional view diagrammatically showing a light emitting apparatus according to a second variation of the present embodiment.

FIG. 7 diagrammatically shows a projector according to the present embodiment.

FIG. 8 is a plan view diagrammatically showing a display according to the present embodiment.

FIG. 9 is a cross-sectional view diagrammatically showing the display according to the present embodiment.

FIG. 10 is a perspective view diagrammatically showing a head mounted display according to the present embodiment.

FIG. 11 diagrammatically shows an image forming apparatus and a light guide of the head-mounted display according to the present embodiment.

FIG. 12 diagrammatically shows a model used in a simulation.

FIG. 13 is a table showing simulation results.

### DESCRIPTION OF EMBODIMENTS

A preferable embodiment of the present disclosure will be described below in detail with reference to the drawings. Note that the embodiment to be described below does not unduly limit the content of the present disclosure described in the claims. Furthermore, all configurations to be described below are not necessarily essential configuration requirements of the present disclosure.

### 1. Light Emitting Apparatus

### 1.1. Overall Configuration

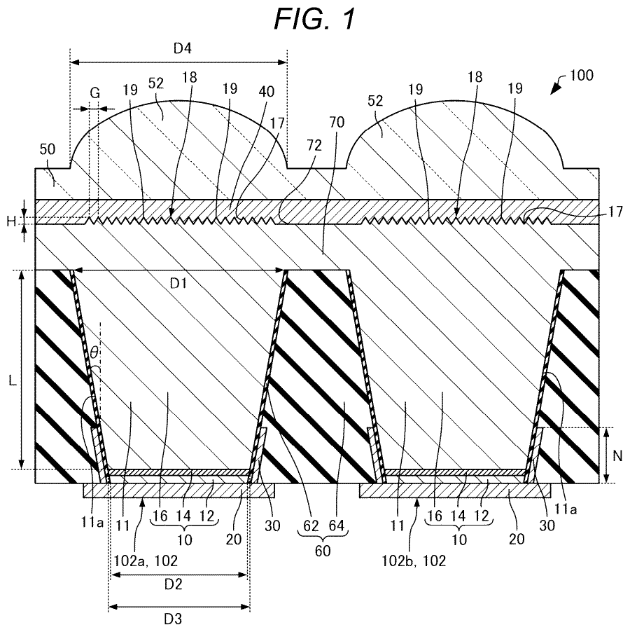

A light emitting apparatus according to an embodiment of the present disclosure will first be described with reference to the drawings. FIG. 1 diagrammatically shows a light emitting apparatus 100 according to the present embodiment.

The light emitting apparatus 100 includes, for example, multiple light emitting elements 102, as shown in FIG. 1. The multiple light emitting elements 102 have, for example, the same structure. In the example shown in FIG. 1, a first light emitting element 102a and a second light emitting element 102b are provided as the multiple light emitting elements 102. The first light emitting element 102a and the second light emitting element 102b are provided side by side when viewed in a stacking direction. The multiple light emitting elements 102 may be arranged in a matrix when viewed in the stacking direction. The light emitting elements 102 each include, for example, a stacked structure 10, a p-electrode 20, a metal layer 30, an n-electrode 40, and a lens layer 50. The light emitting elements 102 are each, for example, an LED. The light emitting apparatus 100 further includes a reflector 60 and a coupling semiconductor layer 70.

Note that the “stacking direction” is the direction in which a p-type semiconductor layer 12 and a light emitting layer 14 of the stacked structure 10 are stacked on each other.

The stacked structure 10 is provided between the p-electrode 20 and the n-electrode 40. In the example shown in FIG. 1, the stacked structure 10 is provided on the p-electrode 20. The stacked structure 10 includes a tapered portion 11 having a tapered shape that increases in width in the direction from the side facing the p-electrode 20 toward the side facing the n-electrode 40. A diameter D1 of an end of the tapered portion 11 that is the end facing the n-electrode 40 is greater than a diameter D2 of an end of the tapered portion 11 that is the end facing the p-electrode 20. In the example shown in FIG. 1, the tapered portion 11 has a trapezoidal shape. A side surface 11a of the tapered portion 11 inclines with respect to the stacking direction. An inclination angle θ of the side surface 11a with respect to the stacking direction is, for example, greater than or equal to 5° but smaller than or equal to 33°, more preferably, greater than or equal to 10° but smaller than or equal to 30° in consideration of process tolerances.

In the present specification, the description will be made on the assumption that the direction from the light emitting layer 14 toward an n-type semiconductor layer 16 of the stacked structure 10 is an “upper” direction, and that the direction from the light emitting layer 14 toward the p-type semiconductor layer 12 of the stacked structure 10 is a “lower” direction, with respect to the light emitting layer 14 of the stacked structure 10 as a reference in the stacking direction.

The “diameter of the tapered portion 11” is the diameter when the tapered portion 11 has a circular planar shape, and is the diameter of the smallest enclosing circle when the tapered portion 11 does not have a circular planar shape. For example, when the tapered portion 11 has a polygonal planar shape, the diameter of the tapered portion 11 is the diameter of the smallest circle enclosing the polygon therein, and when the tapered portion 11 has an elliptical planar shape, the diameter of the tapered portion 11 is the diameter of the smallest circle enclosing the ellipse therein. The same applies to the diameter of the light emitting layer 14 and the diameter of a convex lens 52, both of which will be described later.

The stacked structure 10 includes the p-type semiconductor layer 12, the light emitting layer 14, and the n-type semiconductor layer 16. The p-type semiconductor layer 12, the light emitting layer 14, and the n-type semiconductor layer 16 constitute the tapered portion 11. The p-type semiconductor layer 12, the light emitting layer 14, and the n-type semiconductor layer 16 are made, for example, of group-III nitride semiconductors and have a wurtzite-type crystal structure.

The p-type semiconductor layer 12 is provided on the p-electrode 20. The p-type semiconductor layer 12 is provided between the p-electrode 20 and the light emitting layer 14. The p-type semiconductor layer 12 is, for example, a p-type GaN layer doped with Mg.

The light emitting layer 14 is provided on the p-type semiconductor layer 12. The light emitting layer 14 is provided between the p-type semiconductor layer 12 and the n-type semiconductor layer 16. A diameter D3 of the light emitting layer 14 is, for example, greater than or equal to 0.5 μm but smaller than or equal to 3 μm. The light emitting layer 14 has an i conductivity type intentionally doped with no impurities. The light emitting layer 14 generates light when a current is injected thereinto. The light emitting layer 14 includes, for example, a well layer and a barrier layer. The well layer and the barrier layer are each configured with an i-type semiconductor layer. The well layer is, for example, an InGaN layer. The barrier layer is, for example, a GaN layer. The light emitting layer 14 has a multiple quantum well (MQW) structure configured with the well layer and the barrier layer.

Note that the number of the well layers and the barrier layers, which constitute the light emitting layer 14, is not limited to a specific number. For example, only one well layer may be provided and, in this case, the light emitting layer 14 has a single quantum well (SQW) structure.

The n-type semiconductor layer 16 is provided on the light emitting layer 14. The n-type semiconductor layer 16 is provided between the light emitting layer 14 and the n-electrode 40. In the example shown in FIG. 1, the size of the n-type semiconductor layer 16 in the stacking direction is greater than the size of the p-type semiconductor layer 12 in the stacking direction and the size of the light emitting layer 14 in the stacking direction. The n-type semiconductor layer 16 has a portion that constitutes the tapered portion 11 and a portion that does not constitute the tapered portion 11. The portion that does not constitute the tapered portion 11 is provided between the portion that constitutes the tapered portion 11 and the n-electrode 40. The n-type semiconductor layer 16 is, for example, an n-type GaN layer doped with Si.

The n-type semiconductor layer 16 has a contact surface 17 in contact with the n-electrode 40. The contact surface 17 has a protruding and recessed structure 18. The contact surface 17 has a protruding and recessed shape. The protruding and recessed structure 18 is provided, for example, across the entire surface of the contact surface 17. Protrusions 19 form the protruding and recessed structure 18. Multiple protrusions 19 are provided. The multiple protrusions 19 are, for example, periodically provided. A height H of the protrusions 19 is, for example, greater than or equal to 400 nm. A distance G between the tips of the protrusions 19 adjacent to each other is, for example, smaller than or equal to 230 nm. The protruding and recessed structure 18 may be a moth-eye structure. Note that, although not shown, the multiple protrusions 19 may be provided at random.

In each of the light emitting elements 102, the p-type semiconductor layer 12, the i-type light emitting layer 14, and the n-type semiconductor layer 16 constitute a pin diode. In each of the light emitting elements 102, when a forward bias voltage corresponding to the pin diode is applied to the space between the p-electrode 20 and the n-electrode 40, a current is injected into the light emitting layer 14, so that recombination of electrons and holes occurs in the light emitting layer 14. The recombination causes the light emitting layer 14 to generate light.

The p-electrode 20 is provided on the side opposite the light emitting layer 14 with the p-type semiconductor layer 12 interposed therebetween. The p-type semiconductor layer 12 may be in ohmic contact with the p-electrode 20. The p-electrode 20 is electrically coupled to the p-type semiconductor layer 12. The p-electrode 20 reflects the light generated in the light emitting layer 14 toward the n-electrode 40. The material of the p-electrode 20 is, for example, Au. The p-electrode 20 is one electrode used to inject the current into the light emitting layer 14. For example, data signal potential is applied to the p-electrode 20. The p-electrode 20 in one of the multiple light emitting elements 102 is an electrode independent of those in the other light emitting elements 102.

The metal layer 30 is provided alongside the tapered portion 11. The metal layer 30 is provided alongside the light emitting layer 14. The metal layer 30 is provided at the side surface 11a of the tapered portion 11 via a first layer 62 of the reflector 60. The metal layer 30 surrounds the tapered portion 11 when viewed in the stacking direction. The metal layer 30 is separate from the tapered portion 11. The first layer 62 of the reflector 60 is provided between the metal layer 30 and the tapered portion 11. In the example shown in FIG. 1, the metal layer 30 is coupled to the p-electrode 20. A size N of the metal layer 30 in the stacking direction is, for example, about 1 μm. The metal layer 30 is, for example, an Au layer or an Ag layer. Even when the first layer 62 of the reflector 60 transmits the light generated in the light emitting layer 14, the metal layer 30 reflects the transmitted light toward the n-electrode 40.

The reflector 60 is provided between the tapered portions 11 of the light emitting elements 102 adjacent to each other. The reflector 60 is provided between the light emitting layers 14 of the light emitting elements 102 adjacent to each other. The reflector 60 surrounds the tapered portion 11 when viewed in the stacking direction. The reflector 60 is in contact with the side surface 11a of the tapered portion 11. The refractive index of the reflector 60 is smaller than the refractive index of the stacked structure 10. Specifically, the refractive index of the reflector 60 is smaller than the refractive indices of the p-type semiconductor layer 12, the light emitting layer 14, and the n-type semiconductor layer 16. The difference in the refractive index of GaN between and the material of which the reflector 60 is made is, for example, greater than or equal to 0.8. The material of the reflector 60 is, for example, SiO₂ or Al₂O₃. The reflector 60 reflects the light generated in the light emitting layer 14 toward the n-electrode 40.

A distance L in the stacking direction between an end of the reflector 60 that is the end facing the n-electrode 40 and an end of the light emitting layer 14 that is the end facing the n-electrode 40 is, for example, greater than 0.8 times the diameter D3 of the light emitting layer 14. In the example shown in FIG. 1, the distance L is the distance between the upper end of the reflector 60 and the upper end of the light emitting layer 14. The distance L is, for example, greater than the diameter D3 of the light emitting layer 14. The distance L is, for example, greater than or equal to 2.5 μm but smaller than or equal to 6μm.

The reflector 60 includes, for example, the first layer 62 and a second layer 64. The first layer 62 is provided at the side surface 11a of the tapered portion 11. The first layer 62 surrounds the tapered portion 11 when viewed in the stacking direction. The second layer 64 is provided at the first layer 62 and the metal layer 30. The second layer 64 surrounds the first layer 62, the metal layer 30, and the tapered portion 11 when viewed in the stacking direction.

The coupling semiconductor layer 70 is provided between the n-type semiconductor layers 16 of the light emitting elements 102 adjacent to each other. The coupling semiconductor layer 70 is in contact with the n-type semiconductor layers 16 of the light emitting elements 102 adjacent to each other. In the example shown in FIG. 1, the coupling semiconductor layer 70 is provided between the n-type semiconductor layer 16 of the first light emitting element 102a and the n-type semiconductor layer 16 of the second light emitting element 102b. More specifically, the coupling semiconductor layer 70 is provided between a portion of the n-type semiconductor layer 16 of the first light emitting element 102a that is the portion that does not constitute the tapered portion 11 and a portion of the n-type semiconductor layer 16 of the second light emitting element 102b that is the portion that does not constitute the tapered portion 11. The coupling semiconductor layer 70 is in contact with the n-type semiconductor layer 16 of the first light emitting element 102a and the n-type semiconductor layer 16 of the second light emitting element 102b. The coupling semiconductor layer 70 is continuous with the n-type semiconductor layers 16. The coupling semiconductor layer 70 may be integrated with the n-type semiconductor layers 16 or may be separate therefrom. The material of the coupling semiconductor layer 70 is, for example, the same as the material of the n-type semiconductor layers 16. The impurity concentration of the coupling semiconductor layer 70 may be higher than the impurity concentration of the n-type semiconductor layers 16.

The coupling semiconductor layer 70 is provided on the reflector 60. The coupling semiconductor layer 70 is provided between the reflector 60 and the n-electrode 40. The coupling semiconductor layer 70 has a contact surface 72 in contact with the n-electrode 40. The contact surface 72 has no protruding and recessed structure. The contact surface 72 is a planar surface.

The n-electrode 40 is provided on the n-type semiconductor layer 16 and the coupling semiconductor layer 70. The n-electrode 40 is provided between the n-type semiconductor layer 16 and the lens layer 50 and between the coupling semiconductor layer 70 and the lens layer 50. The n-electrode 40 is provided on the side opposite the light emitting layer 14 with the n-type semiconductor layer 16 interposed therebetween and on the side opposite the reflector 60 with the coupling semiconductor layer 70 interposed therebetween. The n-electrode 40 may be in ohmic contact with the n-type semiconductor layer 16 and the coupling semiconductor layer 70. The n-electrode 40 is electrically coupled to the n-type semiconductor layer 16 and the coupling semiconductor layer 70.

The n-electrode 40 constitutes a common electrode common to the multiple light emitting elements 102. The n-electrode 40 transmits the light generated in the light emitting layer 14. The light generated in the light emitting layer 14 is output via the n-electrode 40. The n-electrode 40 is a transparent electrode made, for example, of ITO. The n-electrode 40 is the other electrode used to inject the current into the light emitting layer 14.

The lens layer 50 is provided on the n-electrode 40. In the example shown in FIG. 1, the lens layer 50 is continuous across the light emitting elements 102 adjacent to each other. The lens layer 50 constitutes, for example, a lens array. The lens layer 50 is, for example, a SiON layer. The lens layer 50 includes the convex lenses 52. The convex lenses 52 each overlap with the corresponding light emitting layer 14 when viewed in the stacking direction. A diameter D4 of the convex lens 52 is, for example, about 6.8 μm. The light generated in the light emitting layer 14 is output via the convex lens 52. The convex lens 52 can narrow the angle of radiation of the output light to improve projection efficiency.

The above example has been described with reference to the case where the n-type semiconductor layer 16 is provided in a portion shifted from the light emitting layer 14 toward the lens layer 50 and the p-type semiconductor layer 12 is provided on the side opposite the lens layer 50 with the light emitting layer 14 interposed therebetween, and the p-type and the n-type may be reversed. That is, although not shown, the p-type semiconductor layer may be provided in a portion shifted from the light emitting layer toward the lens layer, and the n-type semiconductor layer may be provided on the side opposite the lens layer with the light emitting layer interposed therebetween. In this case, the electrode provided at a position shifted from the p-type semiconductor layer toward the lens layer is the p-electrode, and the electrode provided on the side opposite the lens layer with the n-type semiconductor layer interposed therebetween is the n-electrode.

The above example has further been described with reference to the InGaN-based light emitting layer 14, and the light emitting layer 14 can be made of any of various materials capable of emitting light when a current is injected into the material in accordance with the wavelength of emitted light. The light emitting layer 14 can be made of various semiconductor materials, for example, AlGaN-based, AlGaAs-based, InGaAs-based, InGaAsP-based, InP-based, GaP-based, and AlGaP-based semiconductor materials.

### 1.2. Effects and Advantages

The light emitting apparatus 100 includes the stacked structure 10 of the first light emitting element 102a as a first stack, and the stacked structure 10 of the second light emitting element 102b as a second stack. The stacked structure 10 of the first light emitting element 102a includes the p-type semiconductor layer 12 as a first semiconductor layer, the n-type semiconductor layer 16 as a second semiconductor layer, and the light emitting layer 14 as a first light emitting layer provided between the p-type semiconductor layer 12 and the n-type semiconductor layer 16. The stacked structure 10 of the second light emitting element 102b includes the p-type semiconductor layer 12 as a third semiconductor layer, the n-type semiconductor layer 16 as a fourth semiconductor layer, and the light emitting layer 14 as a second light emitting layer provided between the p-type semiconductor layer 12 and the n-type semiconductor layer 16. The light emitting apparatus 100 further includes the coupling semiconductor layer 70 as a fifth semiconductor layer having an n conductivity type, provided between the n-type semiconductor layer 16 of the first light emitting element 102a and the n-type semiconductor layer 16 of the second light emitting element 102b, and being in contact with the n-type semiconductor layer 16 of the first light emitting element 102a and the n-type semiconductor layer 16 of the second light emitting element 102b. The light emitting apparatus 100 further includes the reflector 60 provided between the light emitting layer 14 of the first light emitting element 102a and the light emitting layer 14 of the second light emitting element 102b. The light emitting apparatus 100 further includes the n-electrode 40 as the common electrode that is provided on the side opposite the light emitting layer 14 with the n-type semiconductor layer 16 of the first light emitting element 102a interposed therebetween, on the side opposite the light emitting layer 14 with the n-type semiconductor layer 16 of the second light emitting element 102b interposed therebetween, and on the side opposite the reflector 60 with the coupling semiconductor layer 70 interposed therebetween, and that transmits the light generated in the light emitting layer 14 of the first light emitting element 102a and light generated in the light emitting layer 14 of the second light emitting element 102b. The first light emitting element 102a further includes the p-electrode 20 as a first electrode provided on the side opposite the light emitting layer 14 with the p-type semiconductor layer 12 interposed therebetween, and the second light emitting element 102b includes the p-electrode 20 as a second electrode provided on the side opposite the light emitting layer 14 with the p-type semiconductor layer 12 interposed therebetween.

Therefore, in the light emitting apparatus 100, the resistance of the wiring configured with the n-electrode 40 and the coupling semiconductor layer 70 can be reduced as compared with a case where no coupling semiconductor layer is provided. The amount of current injected into the light emitting layer 14 can thus be increased, so that the luminance of the light from the light emitting layer 14 can be improved. Furthermore, the light use efficiency can be improved, the amount of generated heat can be reduced, the size of an enclosure that is not shown but houses the light emitting apparatus 100 can be reduced, and the cost can be reduced.

In the light emitting apparatus 100, the contact surface 17 of the n-type semiconductor layer 16, where the n-type semiconductor layer 16 is in contact with the n-electrode 40, has the protruding and recessed structure 18, and the contact surface 72 of the coupling semiconductor layer 70, where the coupling semiconductor layer 70 is in contact with the n-electrode 40 is a planar surface. Therefore, in the light emitting apparatus 100, a change in the refractive index at the interface between the n-type semiconductor layer 16 and the n-electrode 40 can be made moderate in the direction from the n-type semiconductor layer 16 toward the n-electrode 40. The light reflected off the interface between the n-type semiconductor layer 16 and the n-electrode 40 can thus be reduced. The light extraction efficiency can therefore be improved. Furthermore, since the contact surface 72 is a planar surface, the light output via the upper side of the coupling semiconductor layer 70 can be reduced, so that crosstalk between the light emitting elements 102 adjacent to each other can be reduced.

In the light emitting apparatus 100, the p-type semiconductor layer 12, the n-type semiconductor layer 16, and the light emitting layer 14 constitute the tapered portion 11, the diameter D1 of the end of the tapered portion 11 that is the end facing the n-electrode 40 is greater than the diameter D2 of the end of the tapered portion 11 that is the end facing the p-electrode 20, the refractive index of the reflector 60 is smaller than the refractive index of the stacked structure 10, and the reflector 60 is in contact with the side surface 11a of the tapered portion 11. Therefore, in the light emitting apparatus 100, the reflector 60 can reflect the light generated in the light emitting layer 14 toward the n-electrode 40.

In the light emitting apparatus 100, the inclination angle θ of the side surface 11a of the tapered portion 11 with respect to the stacking direction is greater than or equal to 5° but smaller than or equal to 33°. Therefore, in the light emitting apparatus 100, screen efficiency can be improved as shown in “7. Experimental examples”, which will be described later. The screen efficiency is calculated by Expression (1) below. Screen efficiency=(amount of light projected onto screen)/(amount of light generated in light emitting layer) (1)

In the light emitting apparatus 100, the distance L in the stacking direction between the end of the reflector 60 that is the end facing the n-electrode 40 and the end of the light emitting layer 14 that is the end facing the n-electrode 40 is greater than 0.8 times the diameter D3 of the light emitting layer 14. Therefore, in the light emitting apparatus 100, the screen efficiency can be improved as shown in “7. Experimental examples”, which will be described later.

### 2. Method for Producing Light Emitting Apparatus

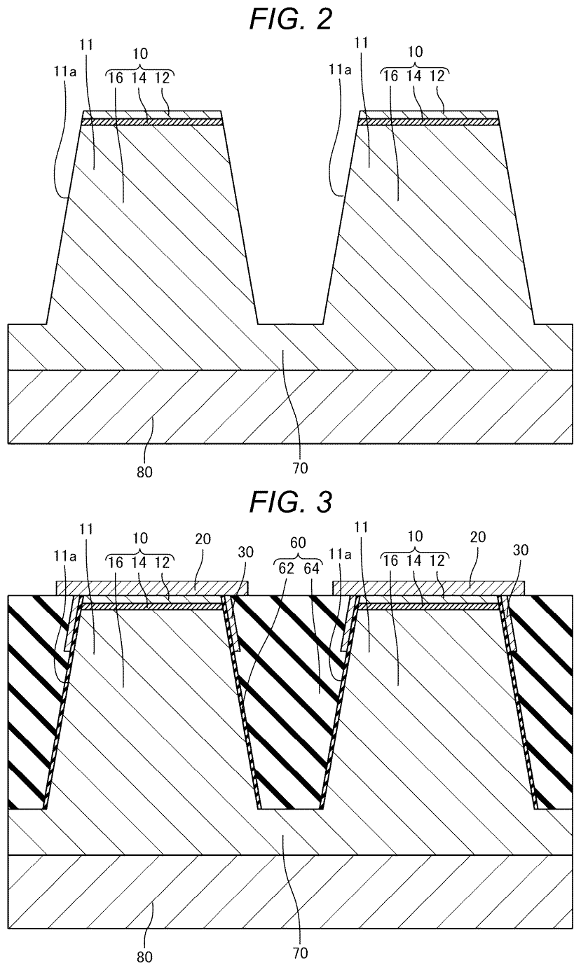

A method for producing the light emitting apparatus 100 according to the present embodiment will next be described with reference to the drawings. FIGS. 2 to 4 are cross-sectional views diagrammatically showing the steps of producing the light emitting apparatus 100 according to the present embodiment.

The n-type semiconductor layer 16, the light emitting layer 14, and the p-type semiconductor layer 12 are epitaxially grown in this order at a growth substrate 80, as shown in FIG. 2. Examples of a method for performing the epitaxial growth may include metal organic chemical vapor deposition (MOCVD) and molecular beam epitaxy (MBE). The stacked structure 10 is formed by the step described above. The growth substrate 80 is, for example, a GaN substrate, a sapphire substrate, a silicon substrate, or a SiC substrate. The growth substrate 80 is a substrate used to epitaxially grow the stacked structure 10.

The stacked structure 10 is then patterned to form the tapered portion 11. The patterning is so performed that the side surface 11a of the tapered portion 11 inclines with respect to the stacking direction. The patterning is further so performed that a portion of the n-type semiconductor layer 16 is left as the coupling semiconductor layer 70. The patterning is performed, for example, by photolithography and etching.

The first layer 62 of the reflector 60 is formed at the side surface 11a of the tapered portion 11, as shown in FIG. 3. The first layer 62 is formed, for example, by chemical vapor deposition (CVD) or sputtering.

The metal layer 30 is then formed at the first layer 62. The metal layer 30 is formed, for example, by sputtering, CVD, or vacuum vapor deposition.

The second layer 64 of the reflector 60 is then formed between the tapered portions 11 adjacent to each other. The second layer 64 is formed, for example, by CVD, sputtering, or spin coating. The reflector 60 including the first layer 62 and the second layer 64 is formed by the step described above.

The p-electrode 20 is then formed on the p-type semiconductor layer 12. The p-electrode 20 is formed, for example, by sputtering, CVD, or vacuum vapor deposition.

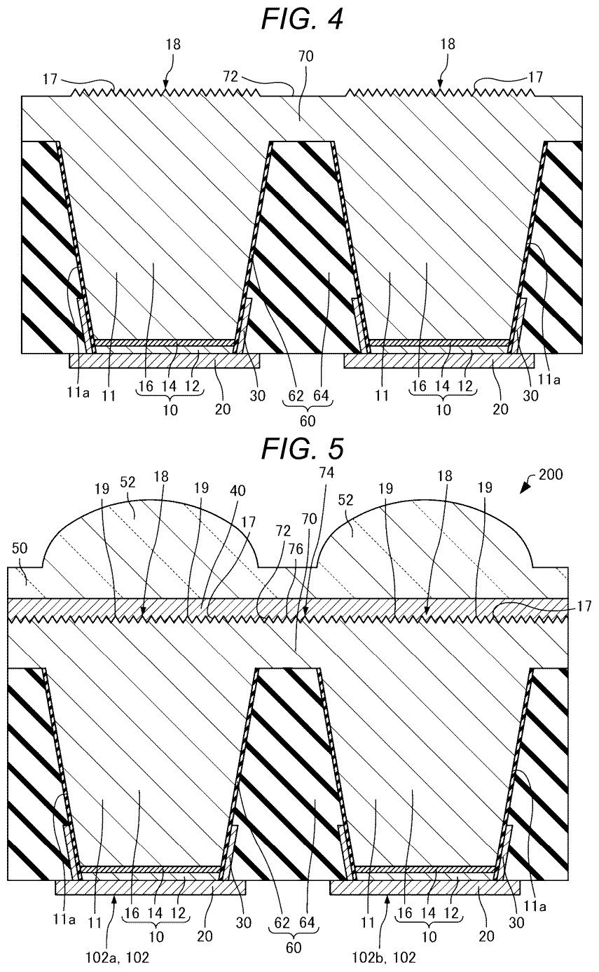

A structure configured with the stacked structure 10, the p-electrode 20, the metal layer 30, the reflector 60, the coupling semiconductor layer 70, and the growth substrate 80 is inverted, and then the growth substrate 80 is removed, as shown in FIG. 4. The upper surface of the n-type semiconductor layer 16 is then patterned to form the protruding and recessed structure 18. The patterning is performed, for example, by photolithography and etching. The upper surface of the coupling semiconductor layer 70 is not etched because the upper surface is covered with a resist layer that is not shown.

The n-electrode 40 is formed on the n-type semiconductor layer 16 and the coupling semiconductor layer 70, as shown in FIG. 1. The n-electrode 40 is formed, for example, by sputtering, CVD, or vacuum vapor deposition.

The lens layer 50 is then formed on the n-electrode 40. The lens layer 50 is formed, for example, by sputtering or CVD. The lens layer 50 is then patterned to form the convex lenses 52. The patterning is performed, for example, by photolithography and etching.

The light emitting apparatus 100 can be produced by the steps described above.

### 3. Variations of Light Emitting Apparatus

### 3.1. First Variation

A light emitting apparatus according to a first variation of the present embodiment will next be described with reference to the drawings. FIG. 5 is a cross-sectional view diagrammatically showing a light emitting apparatus 200 according to the first variation of the present embodiment.

In the following description of the light emitting apparatus 200 according to the first variation of the present embodiment, the members that function in the same manner as the constituent members of the light emitting apparatus 100 according to the present embodiment described above have the same reference characters, and will not be described in detail. The same holds true for a light emitting apparatus according to a second variation of the present embodiment, which will be described later.

In the light emitting apparatus 100 described above, the contact surface 72 of the coupling semiconductor layer 70, where the coupling semiconductor layer 70 is in contact with the n-electrode 40, is a planar surface, as shown in FIG. 1.

In contrast, in the light emitting apparatus 200, the contact surface 72 of the coupling semiconductor layer 70 has a protruding and recessed structure 74, as shown in FIG. 5. The shape of the protruding and recessed structure 74 is, for example, the same as the shape of the protruding and recessed structure 18 of the n-type semiconductor layer 16. The protruding and recessed structure 74 has multiple protrusions 76 continuous with those of the protruding and recessed structure 18 and having the period equal to the period of the protrusions 19 of the protruding and recessed structure 18. The protruding and recessed structure 74 is formed by patterning the upper surface of the coupling semiconductor layer 70, as the protruding and recessed structure 18.

In the light emitting apparatus 200, the contact surface 17 of the n-type semiconductor layer 16, where the n-type semiconductor layer 16 is in contact with the n-electrode 40, and the contact surface 72 of the coupling semiconductor layer 70, where the coupling semiconductor layer 70 is in contact with the n-electrode 40, each have a protruding and recessed structure. Therefore, in the light emitting apparatus 200, the protruding and recessed structures 18 and 74 can be readily formed by etching the entire upper surfaces of the n-type semiconductor layer 16 and the coupling semiconductor layer 70.

### 3.2. Second Variation

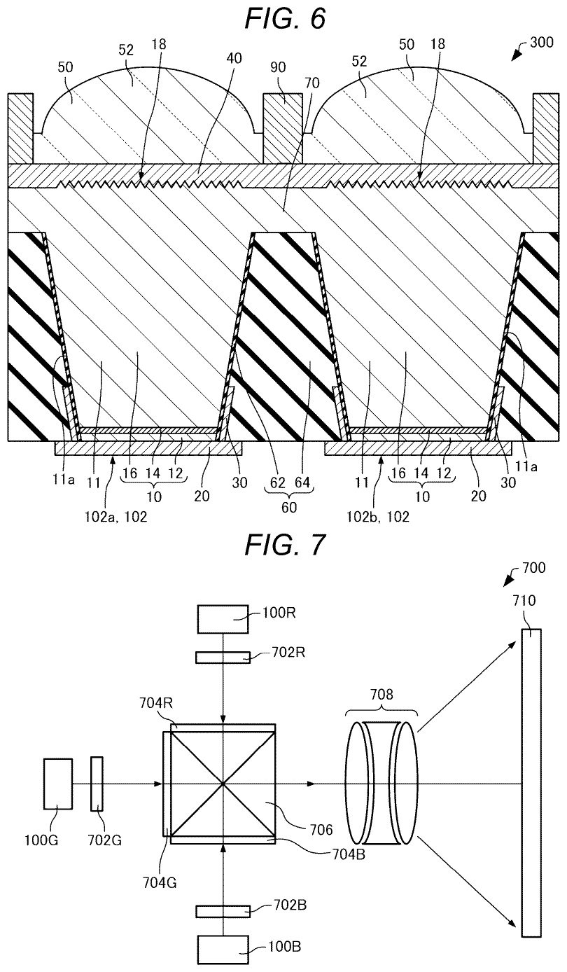

A light emitting apparatus according to the second variation of the present embodiment will next be described with reference to the drawings. FIG. 6 is a cross-sectional view diagrammatically showing a light emitting apparatus 300 according to the second variation of the present embodiment.

The light emitting apparatus 300 differs from the light emitting apparatus 100 described above in that wiring layers 90 are provided, as shown in FIG. 6.

The wiring layers 90 are provided on the n-electrode 40. The wiring layers 90 are provided on the side opposite the coupling semiconductor layers 70 with the n-electrode 40 interposed therebetween. The wiring layers 90 overlap with the coupling semiconductor layers 70 when viewed in the stacking direction. In the example shown in FIG. 6, the wiring layers 90 are in contact with the side surfaces of the lens layers 50. In the light emitting elements 102 adjacent to each other, the lens layers 50 are not continuous with each other. The wiring layers 90, for example, surround the convex lenses 52 when viewed in the stacking direction.

The resistivity of the wiring layers 90 is smaller than the resistivity of the n-electrode 40. The wiring layers 90 are thicker than the n-electrode 40. The wiring layers 90 block the light generated in the light emitting layer 14. The wiring layers 90 are each, for example, an Al layer, a W layer, a Cu layer, or a stack thereof.

The light emitting apparatus 300 includes the wiring layers 90 provided on the side opposite the coupling semiconductor layers 70 with the n-electrode 40 interposed therebetween, and the resistivity of the wiring layers 90 is smaller than the resistivity of the n-electrode 40. Therefore, in the light emitting apparatus 300, the amount of the current injected into the light emitting layer 14 can be further increased, so that the luminance of the light from the light emitting layer 14 can be further improved.

In the light emitting apparatus 300, the wiring layers 90 block the light generated in the light emitting layer 14. Crosstalk between the light emitting elements 102 adjacent to each other can therefore be reduced.

### 4. Projector

A projector according to the present embodiment will next be described with reference to the drawings. FIG. 7 diagrammatically shows a projector 700 according to the present embodiment.

The projector 700 includes, for example, the light emitting apparatus 100 as a light source. Note that FIG. 7 shows the light emitting apparatus 100 in a simplified manner for convenience.

The projector 700 includes an enclosure that is not shown, and a red light source 100R, a green light source 100G, and a blue light source 100B, which are provided in the enclosure and output red light, green light, and blue light, respectively. Note that FIG. 7 shows the red light source 100R, the green light source 100G, and the blue light source 100B in a simplified manner for convenience.

The projector 700 further includes, for example, a first optical element 702R, a second optical element 702G, a third optical element 702B, a first light modulator 704R, a second light modulator 704G, a third light modulator 704B, and a projection apparatus 708, which are all provided in the enclosure. The first light modulator 704R, the second light modulator 704G, and the third light modulator 704B are each, for example, a transmissive liquid crystal light valve. The projection apparatus 708 is, for example, a projection lens.

The light output from the red light source 100R enters the first optical element 702R. The light output from the red light source 100R is collected by the first optical element 702R. Note that the first optical element 702R may have functions other than the light collection. The second optical element 702G and the third optical element 702B may also have functions other than the light collection.

The light collected by the first optical element 702R enters the first light modulator 704R. The first light modulator 704R modulates the incident light in accordance with image information. The projection apparatus 708 then enlarges an image formed by the first light modulator 704R and projects the image onto a screen 710.

The light output from the green light source 100G enters the second optical element 702G. The light output from the green light source 100G is collected by the second optical element 702G.

The light collected by the second optical element 702G enters the second light modulator 704G. The second light modulator 704G modulates the incident light in accordance with the image information. The projection apparatus 708 then enlarges an image formed by the second light modulator 704G and projects the image onto the screen 710.

The light output from the blue light source 100B enters the third optical element 702B. The light output from the blue light source 100B is collected by the third optical element 702B.

The light collected by the third optical element 702B enters the third light modulator 704B. The third light modulator 704B modulates the incident light in accordance with the image information. The projection apparatus 708 then enlarges an image formed by the third light modulator 704B and projects the image onto the screen 710.

The projector 700 further includes, for example, a cross dichroic prism 706, which combines the light output from the first light modulator 704R, the light output from the second light modulator 704G, and the light output from the third light modulator 704B with one another, and guides the combined light to the projection apparatus 708.

The red light modulated by the first light modulator 704R, the green light modulated by the second light modulator 704G, and the blue light modulated by the third light modulator 704B enter the cross dichroic prism 706. The cross dichroic prism 706 is formed by bonding four rectangular prisms to each other, and a dielectric multilayer film that reflects the red light and a dielectric multilayer film that reflects the blue light are disposed at the inner surfaces of the cross dichroic prism 706. The red light, the green light, and the blue light are combined with one another by the dielectric multilayer films into light representing a color image. The combined light is then projected onto the screen 710 by the projection apparatus 708, so that an enlarged image is displayed.

Note that the red light source 100R, the green light source 100G, and the blue light source 100B may control the respective light emitting apparatuses 100, which serves as the pixels of a video, in accordance with the image information to directly form the video without using none of the first light modulator 704R, the second light modulator 704G, and the third light modulator 704B. The projection apparatus 708 may then enlarge the video formed by the red light source 100R, the green light source 100G, and the blue light source 100B, and project the enlarged video onto the screen 710.

Transmissive liquid crystal light valves are used as the light modulators in the example described above, and a light valve other than a liquid crystal light valve or a reflective light valve may be used as each of the light modulators. Examples of such light valves may include a reflective liquid crystal light valve and a digital micromirror device. The configuration of the projection apparatus is changed as appropriate in accordance with the type of a light valve to be used.

The light source can also be used in a light source apparatus of a scan-type image display apparatus including a scanner that is an image forming apparatus that scans a screen with the light from the light source to display an image having a desired size on a display surface.

### 5. Display

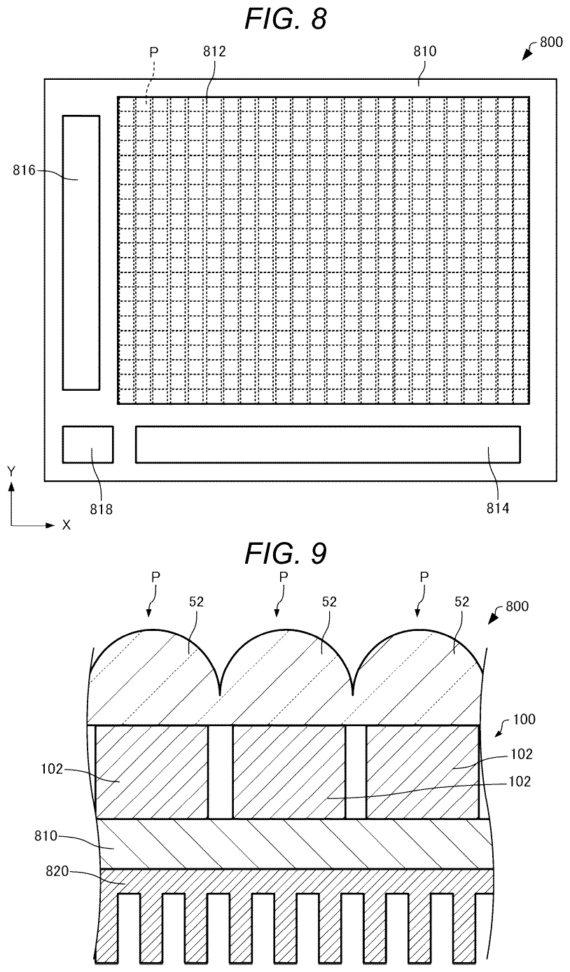

A display serving as an electronic instrument according to the present embodiment will next be described with reference to the drawings. FIG. 8 is a plan view diagrammatically showing a display 800 according to the present embodiment. FIG. 9 is a cross-sectional view diagrammatically showing the display 800 according to the present embodiment. Note that FIG. 8 shows an X-axis and a Y-axis as two axes perpendicular to each other. Note that FIGS. 8 and 9 show the display 800 in a simplified manner for convenience.

The display 800 includes, for example, the light emitting apparatus 100 as a light source. Note that FIGS. 8 and 9 show the light emitting apparatus 100 in a simplified manner for convenience.

The display 800 is a display apparatus that displays an image. The image includes an image displaying only character information. The display 800 is a self-luminous display. The display 800 includes, for example, a circuit substrate 810 and a heat sink 820, as shown in FIGS. 8 and 9.

A drive circuit that drives the light emitting apparatus 100 is mounted on the circuit substrate 810. The drive circuit is, for example, a circuit including a complementary metal oxide semiconductor (CMOS). The drive circuit drives the light emitting apparatus 100 based, for example, on input image information. Although not shown, a light transmissive substrate that protects the circuit substrate 810 is disposed on the circuit substrate 810.

The circuit substrate 810 has, for example, a display region 812, a data line driving circuit 814, a scan line driving circuit 816, and a control circuit 818.

The display region 812 is configured with multiple pixels P. In the example shown in FIG. 8, the pixels P are arranged along the X-axis and the Y-axis.

Although not shown, the circuit substrate 810 is provided with multiple scan lines and multiple data lines. For example, the scan lines extend along the X-axis, and the data lines extend along the Y-axis. The scan lines are coupled to the scan line driving circuit 816. The data lines are coupled to the data line driving circuit 814. The pixels P are provided in correspondence with the intersections of the scan lines and the data lines.

The pixels P each include, for example, a light emitting element 102 and a pixel circuit that is not shown. The pixel circuit includes a switching transistor that functions as a switch of the pixel P. The gate of the switching transistor is coupled to the corresponding scan line, and one of the source and the drain of the switching transistor is coupled to the corresponding data line.

The data line driving circuit 814 and the scan line driving circuit 816 are circuits that control the operation of driving the light emitting apparatus 100 that forms the pixels P. The control circuit 818 controls the operation of displaying an image.

Image data is supplied to the control circuit 818 from an upper-level circuit. The control circuit 818 supplies the data line driving circuit 814 and the scan line driving circuit 816 with various signals based on the image data.

When a scan line is selected by a scan signal activated by the scan line driving circuit 816, the switching transistor of the selected pixel P is turned on. At this point in time, the data line driving circuit 814 supplies the selected pixel P with a data signal via the corresponding data line, so that the light emitting elements 102 of the selected pixel P emits light in accordance with the data signal.

The heat sink 820 is in contact with the circuit substrate 810. The material of the heat sink 820 is, for example, a metal such as Cu or Al. The heat sink 820 dissipates heat generated in the light emitting apparatus 100.

### 6. Head Mounted Display

### 6.1. Overall Configuration

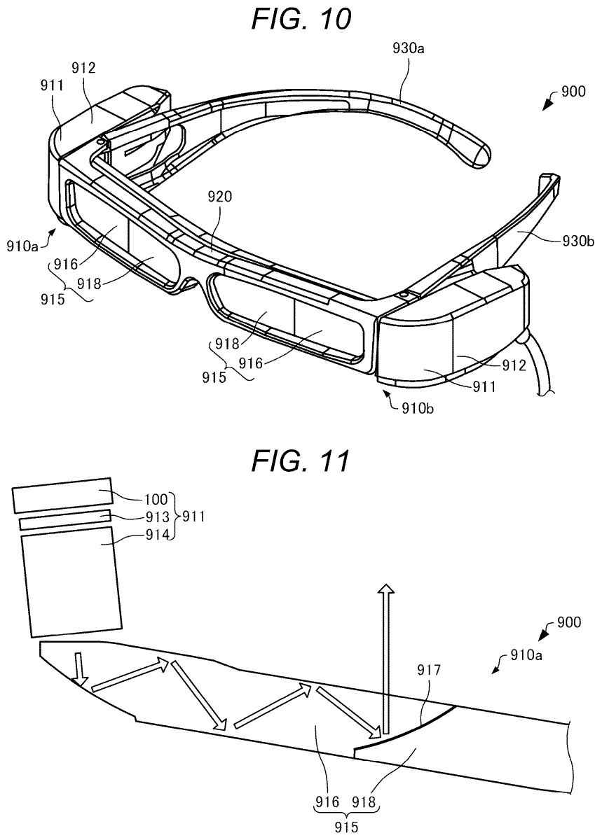

A head mounted display as the electronic instrument according to the present embodiment will next be described with reference to the drawings. FIG. 10 is a perspective view diagrammatically showing a head mounted display 900 according to the present embodiment.

The head mounted display 900 is a head-mounted-type display having an appearance of glasses, as shown in FIG. 10. The head mounted display 900 is worn on an observer's head. The observer means a user who uses the head mounted display 900. The head mounted display 900 allows the observer to visually recognize video light carrying virtual images and visually recognize a see-through outer environment image.

The head mounted display 900 includes, for example, a first display unit 910a, a second display unit 910b, a frame 920, a first temple 930a, and a second temple 930b.

The first display unit 910a and the second display unit 910b display images. Specifically, the first display unit 910a displays a virtual image for the observer's right eye. The second display unit 910b displays a virtual image for the observer's left eye. The display units 910a and 910b each include, for example, an image forming apparatus 911 and a light guide 915.

The image forming apparatus 911 forms image light. The image forming apparatus 911 includes, for example, a light source, a projection apparatus, and other optical systems, and an external member 912. The external member 912 houses the light source and the projection apparatus.

The light guide 915 covers the front side of the observer's eye. The light guide 915 guides the image light formed by the image forming apparatus 911, and causes the observer to visually recognize the outer environment light and the image light with the two types of light overlapping with each other. Note that the image forming apparatus 911 and the light guide 915 will be described later in detail.

The frame 920 supports the first display unit 910a and the second display unit 910b. The frame 920 surrounds, for example, the display units 910a and 910b. In the example shown in FIG. 10, the image forming apparatus 911 of the first display unit 910a is attached to one end of the frame 920. The image forming apparatus 911 of the second display unit 910b is attached to the other end of the frame 920.

The first temple 930a and the second temple 930b extend from the frame 920. In the example shown in FIG. 10, the first temple 930a extends from the one end of the frame 920. The second temple 930b extends from the other end of the frame 920.

The first temple 930a and the second temple 930b are placed on the observer's ears when the observer wears the head mounted display 900. The observer's head is located between the temples 930a and 930b.

### 6.2. Image Forming Apparatus and Light Guide

FIG. 11 diagrammatically shows the image forming apparatus 911 and the light guide 915 of the first display unit 910a of the head mounted display 900. Note that the first display unit 910a and the second display unit 910b basically have the same configuration. The following description of the first display unit 910a can therefore be applied to the second display unit 910b.

The image forming apparatus 911 includes, for example, the light emitting apparatus 100 as a light source, a light modulator 913, and a projection apparatus 914 for image formation, as shown in FIG. 11. Note that FIG. 11 shows the light emitting apparatus 100 in a simplified manner for convenience.

The light modulator 913 modulates the light incident from the light emitting apparatus 100 in accordance with image information, and outputs video light. The light modulator 913 is a transmissive liquid crystal light valve. Note that the light emitting apparatus 100 may be a self-luminous light emitting apparatus that emits light in accordance with input image information. In this case, the light modulator 913 is not provided.

The projection apparatus 914 projects the video light output from the light modulator 913 toward the light guide 915. The projection apparatus 914 is, for example, a projection lens. The lens that constitutes the projection apparatus 914 may be a lens having an axisymmetric lens surface.

The light guide 915 is fixed to a lens barrel of the projection apparatus 914, for example, with screws, so that the light guide 915 is precisely positioned with respect to the projection apparatus 914. The light guide 915 includes, for example, a video light guide member 916, which guides the video light, and a see-through member 918 for see-through observation.

The video light output from the projection apparatus 914 enters the video light guide member 916. The video light guide member 916 is a prism that guides the video light toward the observer's eye. The video light having entered the video light guide member 916 is repeatedly reflected off the inner surfaces of the video light guide member 916, is then reflected off a reflection layer 917, and is output from the video light guide member 916. The video light output from the video light guide member 916 reaches the observer's eye. The reflection layer 917 is made, for example, of metal, or configured, for example, with a dielectric multilayer film. The reflection layer 917 may be a half-silvered mirror.

The see-through member 918 is adjacent to the video light guide member 916. The see-through member 918 is fixed to the video light guide member 916. The outer surface of the see-through member 918 is, for example, continuous to the outer surface of the video light guide member 916. The see-through member 918 allows the observer to see the outer environment light in see-through observation. In addition to the function of guiding the video light, the video light guide member 916 also has the function of allowing the observer to see the outer environment light in see-through observation. Note that the head mounted display 900 may have a configuration that does not allow the observer to see the outer environment light in see-through observation.

Note that the electronic instrument in which the light emitting apparatus according to the present embodiment is used is not limited to a display or a head mounted display. The light emitting apparatus according to the present embodiment can be used, for example, in an instrument including a display apparatus disposed in the vicinity of an eye, such as a personal computer, a digital scope, digital binoculars, a digital still camera, and a video camcorder; a mobile phone; a smartphone; a personal digital assistant (PDA); a car navigation system, an in-vehicle display unit, a light radiating illuminator, and a flexible display.

### 7. Experimental Examples

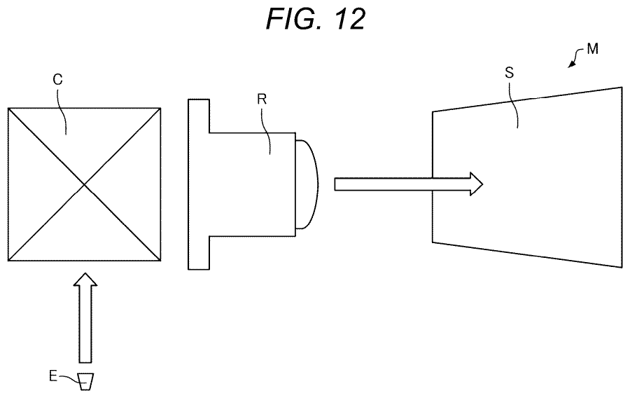

A simulation was performed by using light emitting elements corresponding to the light emitting elements 102 shown in FIG. 1, and the screen efficiency was calculated based on Expression (1) described above. Light Tools produced by Synopsys, Inc. was used as simulation software. FIG. 12 diagrammatically shows a model M used in the simulation. The light emitted from a light emitting element E is reflected off a cross dichroic prism C, and then projected onto a screen S by a projection lens R, as shown in FIG. 12.

In the light emitting element E, the diameter D1 of the upper end of the tapered portion was 6.8 μm or smaller. The diameter D3 of the light emitting layer was 3 μm. The diameter D4 of the convex lens shown in FIG. 1 was 6.8 μm. The size N of the metal layer in the stacking direction was 1μm. Thereafter, the distance L between the upper end of the reflector and the upper end of the light emitting layer shown in FIG. 1 and the inclination angle θ of the side surface of the tapered portion with respect to the stacking direction were varied to calculate the screen efficiency.

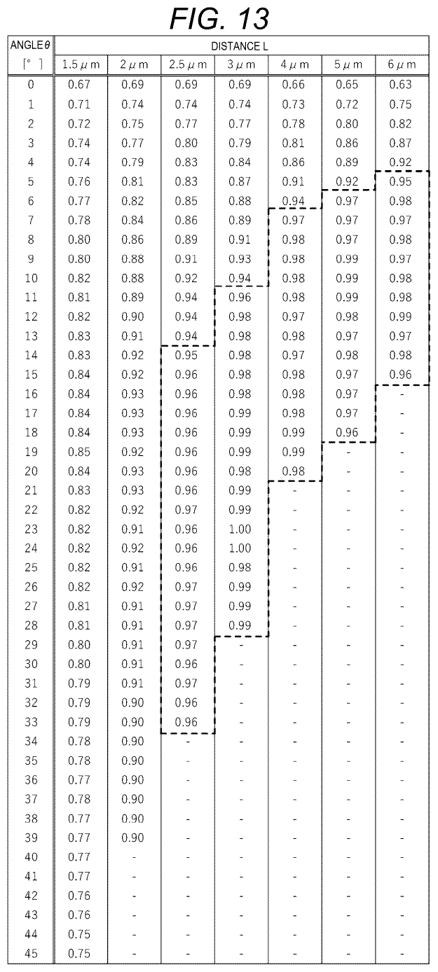

FIG. 13 is a table showing results of the simulation. The screen efficiency in FIG. 13 is expressed by values normalized by the maximum screen efficiency. Note in FIG. 13 that a range within which the screen efficiency is greater than or equal to 0.95 is surrounded by the broken line. In FIG. 13, a case where the diameter of the upper end of the tapered portion exceeds the value corresponding to the diameter D4 of the convex lens is indicated by “−”.

As shown in FIG. 13, it was found that when the distance L is greater than or equal to 2.5 μm, that is, when the distance L is greater than 0.8 times the diameter of the light emitting layer, and when the angle θ is greater than or equal to 5° but smaller than or equal to 33°, the screen efficiency is likely to be 0.95 or greater, which are very high values.

The embodiment and variations thereof described above are merely examples, and the present disclosure is not limited thereto. For example, the embodiment and variations thereof can be combined with each other as appropriate.

The present disclosure includes a configuration that is substantially the same as the configuration described in the embodiment, such as a configuration having the same function, using the method, and providing the same result, or a configuration having the same object and providing the same advantages. The present disclosure further includes a configuration in which a non-essential portion of the configuration described in the embodiment is replaced with another portion. The present disclosure further includes a configuration providing effects and advantages that are the same as those provided by the configuration described in the embodiment, or a configuration that can achieve the same object. The present disclosure further includes the configuration described in the embodiment to which a known technology is added.

The following contents can be derived from the embodiment and variations thereof described above.

An aspect of a light emitting apparatus includes:
a first stack including a first semiconductor layer having a first conductivity type, a second semiconductor layer having a second conductivity type different from the first conductivity type, and a first light emitting layer provided between the first semiconductor layer and the second semiconductor layer;
a second stack including a third semiconductor layer having the first conductivity type, a fourth semiconductor layer having the second conductivity type, and a second light emitting layer provided between the third semiconductor layer and the fourth semiconductor layer;
a fifth semiconductor layer provided between the second semiconductor layer and the fourth semiconductor layer, being in contact with the second semiconductor layer and the fourth semiconductor layer, and having the second conductivity type;
a reflector provided between the first light emitting layer and the second light emitting layer;
a first electrode provided on a side opposite the first light emitting layer with the first semiconductor layer interposed therebetween;
a second electrode provided on a side opposite the second light emitting layer with the third semiconductor layer interposed therebetween; and
a common electrode provided on a side opposite the first light emitting layer with the second semiconductor layer interposed therebetween, on a side opposite the second light emitting layer with the fourth semiconductor layer interposed therebetween, and on a side opposite the reflector with the fifth semiconductor layer interposed therebetween, and transmitting light generated in the first light emitting layer and light generated in the second light emitting layer.

According to the light emitting apparatus, the luminance of the light from the light emitting apparatus can be improved.

In an aspect of the light emitting apparatus,
a surface of the second semiconductor layer that is a surface in contact with the common electrode and a surface of the fourth semiconductor layer that is a surface in contact with the common electrode may have a protruding and recessed structure, and
a surface of the fifth semiconductor layer that is a surface in contact with the common electrode may be a planar surface.

According to the light emitting apparatus, the light extraction efficiency can be improved, and crosstalk between the two stacks can be reduced.

In an aspect of the light emitting apparatus,
a surface of the second semiconductor layer that is a surface in contact with the common electrode, a surface of the fourth semiconductor layer that is a surface in contact with the common electrode, and a surface of the fifth semiconductor layer that is a surface in contact with the common electrode may have a protruding and recessed structure.

According to the light emitting apparatus, the protruding and recessed structure can be readily formed.

In an aspect of the light emitting apparatus,
the first semiconductor layer, the second semiconductor layer, and the first light emitting layer may constitute a tapered portion,
a diameter of an end of the tapered portion that is an end facing the common electrode may be greater than a diameter of an end of the tapered portion that is an end facing the first electrode,
a refractive index of the reflector may be smaller than a refractive index of the first stack, and
the reflector may be in contact with a side surface of the tapered portion.

According to the light emitting apparatus, the light generated in the first light emitting layer can be reflected off the reflector toward the common electrode.

In an aspect of the light emitting apparatus,
an inclination angle of a side surface of the tapered portion with respect to a stacking direction in which the first semiconductor layer and the first light emitting layer are stacked on each other may be greater than or equal to 5° but smaller than or equal to 33°.

According to the light emitting apparatus, the screen efficiency can be improved.

In an aspect of the light emitting apparatus,
a distance in the stacking direction between an end of the reflector that is an end facing the common electrode and an end of the first light emitting layer that is an end facing the common electrode may be greater than 0.8 times a diameter of the first light emitting layer.

According to the light emitting apparatus, the screen efficiency can be improved.

In an aspect of the light emitting apparatus,
the light emitting apparatus may include a wiring layer provided on a side opposite the fifth semiconductor layer with the common electrode interposed therebetween, and
resistivity of the wiring layer may be smaller than resistivity of the common electrode.

According to the light emitting apparatus, the amount of current injected into the first light emitting layer and the second light emitting layer can be further increased.

In an aspect of the light emitting apparatus,
the wiring layer may block the light generated in the first light emitting layer and the light generated in the second light emitting layer.

According to the light emitting apparatus, crosstalk between the two stacks can be reduced.

An aspect of a projector includes
the aspect of the light emitting apparatus.

An aspect of an electronic instrument includes
the aspect of the light emitting apparatus.

What is claimed is:

1. A light emitting apparatus, comprising:
a first stack including a first semiconductor layer having a first conductivity type, a second semiconductor layer having a second conductivity type different from the first conductivity type, and a first light emitting layer provided between the first semiconductor layer and the second semiconductor layer;
a second stack including a third semiconductor layer having the first conductivity type, a fourth semiconductor layer having the second conductivity type, and a second light emitting layer provided between the third semiconductor layer and the fourth semiconductor layer;
a fifth semiconductor layer provided between the second semiconductor layer and the fourth semiconductor layer, being in contact with the second semiconductor layer and the fourth semiconductor layer, and having the second conductivity type;
a reflector provided between the first light emitting layer and the second light emitting layer;
a first electrode provided on a side opposite the first light emitting layer with the first semiconductor layer interposed therebetween;
a second electrode provided on a side opposite the second light emitting layer with the third semiconductor layer interposed therebetween; and
a common electrode provided on a side opposite the first light emitting layer with the second semiconductor layer interposed therebetween, on a side opposite the second light emitting layer with the fourth semiconductor layer interposed therebetween, and on a side opposite the reflector with the fifth semiconductor layer interposed therebetween, and configured to transmit light generated in the first light emitting layer and light generated in the second light emitting layer.

2. The light emitting apparatus according to claim 1, wherein
a surface of the second semiconductor layer that is a surface in contact with the common electrode and a surface of the fourth semiconductor layer that is a surface in contact with the common electrode each have a protruding and recessed structure, and
a surface of the fifth semiconductor layer that is a surface in contact with the common electrode is a planar surface.

3. The light emitting apparatus according to claim 1, wherein
a surface of the second semiconductor layer that is a surface in contact with the common electrode, a surface of the fourth semiconductor layer that is a surface in contact with the common electrode, and a surface of the fifth semiconductor layer that is a surface in contact with the common electrode each have a protruding and recessed structure.

4. The light emitting apparatus according to claim 1, wherein
the first semiconductor layer, the second semiconductor layer, and the first light emitting layer constitute a tapered portion,
a diameter of an end of the tapered portion that is an end facing the common electrode is greater than a diameter of an end of the tapered portion that is an end facing the first electrode,
a refractive index of the reflector is smaller than a refractive index of the first stack, and
the reflector is in contact with a side surface of the tapered portion.

5. The light emitting apparatus according to claim 4, wherein
an inclination angle of the side surface of the tapered portion with respect to a stacking direction in which the first semiconductor layer and the first light emitting layer are stacked on each other is greater than or equal to 5° but smaller than or equal to 33°.

6. The light emitting apparatus according to claim 5, wherein
a distance in the stacking direction between an end of the reflector that is an end facing the common electrode and an end of the first light emitting layer that is an end facing the common electrode is greater than 0.8 times a diameter of the first light emitting layer.

7. The light emitting apparatus according to claim 1, further comprising:
a wiring layer provided on a side opposite the fifth semiconductor layer with the common electrode interposed therebetween,
wherein resistivity of the wiring layer is smaller than resistivity of the common electrode.

8. The light emitting apparatus according to claim 7, wherein
the wiring layer blocks the light generated in the first light emitting layer and the light generated in the second light emitting layer.

9. A projector, comprising:
the light emitting apparatus according to claim 1.

10. An electronic instrument, comprising:
the light emitting apparatus according to claim 1.
